(19) United States
(12) Patent Application Publication
(10) Pub. No.: US 2026/0057935 A1
(43) Pub. Date: Feb. 26, 2026

(54) RAPID PROGRAMMING OF MEMORY ARRAYS WITH CONCURRENT PROGRAMMING AND VERIFICATION

(71) Applicant: Applied Materials, Inc., Santa Clara, CA (US)

(72) Inventor: Frank Tzen-Wen Guo, Danville, CA (US)

(73) Assignee: Applied Materials, Inc., Santa Clara, CA (US)

(21) Appl. No.: 18/815,792

(22) Filed: Aug. 26, 2024

(51) Int. Cl. G11C 13/00

(52) U.S. Cl. CPC G11C 13/0069; G11C 13/0061; G11C 2013/0078

(57) ABSTRACT

A controller may receive a target conductance associated with the resistive memory element. The controller may then enter a program mode. The controller may adjust, while in the program mode, a conductance associated with the resistive memory element until the conductance is within a first range of the target conductance. The controller may then determine whether the conductance is within a second range of the target conductance. The controller may, while still in the program mode, apply electrical pulses to the resistive memory element that adjust the conductance associated with the resistive memory element until the conductance is within the second range of the target conductance.

### TECHNICAL FIELD

This disclosure is generally related to methods for rapidly programming memory elements in a memory array. More specifically, this disclosure describes an autoprogramming circuit that may perform a two-stage programming process while in a programming mode.

### BACKGROUND

A computing device may store data in one or more memory elements. A resistive memory element may include a material, such as a metal oxide, whose resistance values may be used to represent data values. A voltage may be applied to a resistive memory element to alter the resistance value of the resistive memory element, thereby altering the value of the data stored in the resistive memory element.

### SUMMARY

In some embodiments, a method may include receiving, by a controller that is associated with a resistive memory element, a target conductance associated with the resistive memory element. The method may also include adjusting, by the controller and while the controller is in a program mode, a conductance associated with the resistive memory element until the conductance is within a first range of the target conductance. The method may additionally include determining, by the controller and while the controller is in a program mode, whether the conductance is within a second range of the target conductance. The method may further include applying, by the controller and while the controller is in the program mode, electrical pulses to the resistive memory element that adjust the conductance associated with the resistive memory element until the conductance is within the second range of the target conductance.

In some embodiments, a system may include a resistive memory element and a controller that is coupled to the resistive memory element and is configured to perform operations including receiving, target conductance associated with the resistive memory element. The operations may also include adjusting, while the controller is in a program mode, a conductance associated with the resistive memory element until the conductance is within a first range of the target conductance. The operations may additionally include determining whether the conductance is within a second range of the target conductance. The operations may further include applying, while the controller is in the program mode, electrical pulses to the resistive memory element that adjust the conductance associated with the resistive memory element until the conductance is within the second range of the target conductance.

In some embodiments, a controller may coupled to a resistive memory element and may be configured to perform operations including receiving a target conductance associated with the resistive memory element. The operations may also include adjusting, while the controller is in a program mode, a conductance associated with the resistive memory element until the conductance is within a first range of the target conductance. The operations may additionally include determining, by the controller, whether the conductance is within a second range of the target conductance. The operations may further include applying, by the controller and while the controller is in the program mode, electrical pulses to the resistive memory element that adjust the conductance associated with the resistive memory element until the conductance is within the second range of the target conductance.

In any embodiments, any or all of the following features may be implemented in any combination and without limitation. While in the program mode, the controller may adjust an offset voltage associated with the resistive memory element. The resistive memory element may be embedded within an array having a plurality of resistive memory elements. Each resistive memory element in the plurality of resistive memory elements may be associated with a unique controller in an array of controllers. Determining whether the conductance is within a second range of the target conductance may include determining, by a phase shift detector associated with the controller and based on a phase shift of an electrical pulse applied by the controller to the resistive memory element, a change in conductance of the resistive memory element. The controller may adjust a pulse duration of the electrical pulses based on a difference between the conductance of the resistive memory element and the target conductance. A resistive memory element may be selected by providing a row value corresponding to the resistive memory element to a row decoder; and providing a column value corresponding to the resistive memory element to a column multiplexer. The controller may include an auto-offset zeroing circuit that may be configured while the controller is in a program mode to adjust an offset voltage associated with the resistive memory element. The controller may include a cycling circuit that may be configured to generate clocked pulses that may be used to generate the electrical pulses. A tapping circuit may be configured to receive a data signal from a column multiplexer associated with the resistive memory element. A tripping detector circuit may be configured to, in response to receiving a signal from a flip flop, enable the controller to apply the electrical pulses. A phase-shift detector may be configured to determine a timing difference between an electrical pulse applied to the resistive memory element and a reference electrical pulse provided from a reference electrical pulse generator. A go-stop detector may be configured to, in response to receiving an output from the phase shift detector, provide the signal to the tripping detector. The controller may be configured to adjust, while the controller is in a program mode, an offset voltage associated with the resistive memory element. A phase-shift detector may include a first input that is configured to receive a program current from the resistive memory element; a second input that is configured to receive a reference current from a reference pulse generator; a first output that is configured to transmit a first digital output signal based on the program current; and a second output that is configured to transmit a second digital output signal based on the reference current. The controller may include a latch pulse generator that may be configured to generate a pulse signal based on the first digital output signal and the second digital output signal, the pulse signal having a duration that is substantially similar to a time difference between the first digital output signal and the second digital output signal. Groups of resistive memory elements may share unique controllers in an array of controllers. The controller may include a read mode that applies a read bias to a memory array during a read operation, and the read mode comprises a different operating mode than the program mode. The controller may include a flip-flop that is configured to receive the pulse signal; and generate, based on the duration of the pulse signal, a signal that is receivable by a tripping detector of the controller.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a diagram of a system having an array of resistive memory elements, according to some embodiments.

FIG. 2 illustrates a resistive memory element, according to some embodiments.

FIG. 3 illustrates a flowchart of a method for programming a resistive memory element, according to some embodiments.

FIG. 4 illustrates a decision tree for programming a resistive memory element, according to some embodiments.

FIG. 5 illustrates a system for programming and verifying a resistive memory element, according to some embodiments.

FIG. 6 illustrates a sensing circuit, according to some embodiments.

FIG. 7 illustrates a phase shift detector circuit and go-stop detector circuit, according to some embodiments.

FIG. 8 illustrates a go-stop detector circuit, according to some embodiments.

### DETAILED DESCRIPTION

Described herein are embodiments for a controller that may be used to program a resistive memory element. The controller may program the resistive memory element by adjusting a conductance associated with the resistive memory element. For example, the controller may apply a voltage to the resistive memory element that may adjust the conductance of the resistive memory element. Traditionally, resistive memory elements have been programmed by trial and error. For example, a controller for an array of resistive memory elements would begin in a program mode in which the controller would apply a first voltage to alter the conductance of a resistive memory element. After applying the voltage, the controller would switch to a read mode in order to verify that the conductance is close to a desired conductance value. If the resistive memory element was not close to the desired conductance value, the controller would switch back to a program mode to apply a second voltage to the resistive memory element to adjust the conductance a second time. After applying the second voltage, the controller would switch back to the read mode to begin the process again, repeating the read-and-program steps iteratively until the conductance of the resistive memory element had reached the desired value. The iterative “trial and error” method was energy-inefficient and time-inefficient and involved re-biasing the entire array of resistive memory elements multiple times to adjust the conductance value of a single element of the resistive memory element array. The embodiments described herein overcome these and other technical challenges that exist in current controller schemes.

Furthermore, since each memory cell is different, this iterative process had to be performed to program every individual memory cell. It was impossible to, for example, apply a single known voltage two different memory cells and expect the same resulting output. For example, to store a particular label value (e.g., a three-bit value) in one memory cell may require a different programming voltage to be applied when compared to a second memory cell, even in the same array. Memory arrays with relatively short retention times need much faster programming techniques in order to be viable. For example, memory arrays with retention times as short as one day or one week cannot be viable using techniques that take days or weeks to program.

In the embodiments described herein, a controller may receive a target conductance associated with the resistive memory element. The controller may then enter a program mode. The controller may adjust, while in the program mode, a conductance associated with the resistive memory element until the conductance is within a first range of the target conductance. The controller may then determine whether the conductance is within a second range of the target conductance. The controller may, while still in the program mode, apply electrical pulses to the resistive memory element that adjust the conductance associated with the resistive memory element until the conductance is within the second range of the target conductance. This greatly improves the efficiency with which memory arrays may be programmed, particularly in the case of high-density memory arrays. For example, if each memory element in a 20 Mb array requires the iterative approach of switching between program and control modes described above, it would take a prohibitive amount of time to fully program the array (e.g., days or even weeks). The auto-programming techniques described below allow the entire memory array to be programmed in considerably less time.

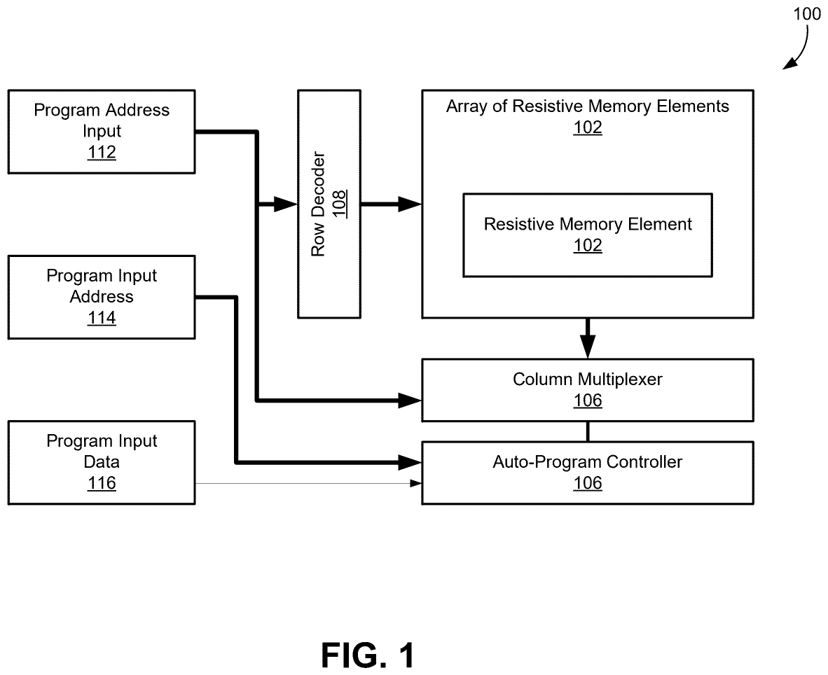

FIG. 1 illustrates a diagram of a system 100 including a controller 104 for an array of resistive memory elements 102, according to some embodiments. The array of resistive memory elements 102 may include rows and columns of resistive memory elements, where each unique row-column pair may correspond to a unique resistive memory element. For example, the array of resistive memory elements 102 may include 1024 columns and 1024 rows, or any other suitable number of columns and rows. The array of resistive memory elements 102 may be electrically coupled to a row decoder 108. The row decoder 108 may receive a program address input 112 that may include a row corresponding to a resistive memory element in the array of resistive memory elements 102. The array of resistive memory elements 102 may be further coupled to a column multiplexer 106. The column multiplexer 106 may receive the program address input 112 that may include a column corresponding to the resistive memory element in the array of resistive memory elements 102. The column multiplexer 106 may, when used in tandem with the row decoder 108, provide the controller 104 with access to an individual resistive memory element in the array of resistive memory elements 102. In some embodiments, the column multiplexer 106 may be a part of the controller 104. In some embodiments, the column multiplexer 106 may be housed in the same housing as the controller 104.

The controller 104 may receive a program input control 114 that may cause the controller to begin programming the resistive memory element. For example, the program input control 114 may cause the controller 104 to enter a “program mode.” The controller 104 may also receive program input data 116 that the controller 104 may use to program the resistive memory element. In some embodiments, the program input data 116 may be a target conductivity for the resistive memory element. In some embodiments, the program input data 116 may include a logic “1” or logic “0”, which may be translated into the target conductivity by the controller 104. In some embodiments, the array of resistive memory elements 102 may include multiple controllers. In some embodiments, several resistive memory elements 103 may be programmed in parallel by the multiple controller. In some embodiments, programming the resistive memory elements may be performed synchronously (e.g., with a clock signal) or asynchronously (e.g., without a clock signal). In some embodiments, each resistive memory element 103 in the array of resistive memory elements 102 may be paired with a unique controller 104. In some embodiments, a set of resistive memory elements 103 that have been selected for programming may be paired with a controller 104.

The array of resistive memory elements 102 may have considerable variation between the individual memory elements. For example, characteristics (programming voltages, programming time, output currents, how output current changes based on voltage inputs, etc.) may vary as much is 20% between memory elements. Each of the memory elements in the array of resistive memory elements 102 may be programmed to multiple levels. For example, some embodiments may use 16 conductance levels corresponding to 4-bits per level. The system 100 may include greater than 1 million bit cells, greater than 10 million bit cells, greater than 50 million bit cells, or even greater than 100 million bit cells. The array of resistive memory elements 102 may represent one section or tile in the overall memory array, such as a 1k by 1k tile of memory elements. The program input data 116 may be stored separately in a fast, low-cause memory (e.g., a 3D NAND flash memory) that may provide high density memory storage. These values may be loaded into the controller 104 to program each of the resistive memory elements.

The controller 104 may represent an auto-program controller that is configured to program memory elements in the array of resistive memory elements 102. The auto program controller is different from previous programming solutions because the auto program controller may independently provide programming voltages to memory elements and read the resulting output without switching modes. As described in detail below, the auto program controller may iteratively program and read the results very quickly until each memory element is individually programmed. In contrast, previous solutions did not use an independent controller 104 with the auto program functionality. Instead, previous solutions provided the program address input 112 and a guess at the correct programming voltage to the array of resistive memory elements 102. The controller would then switch to a read mode, apply read bias voltages to the array of resistive memory element 102 and read that particular memory location. This would take place at an external or central controller for the entire memory array. This external or central program controller would then compare the output value to the program input data 116 to determine whether the write operation was correct. If not, the central controller would then switch back to a programming mode and apply a new voltage to the memory element. This trial-and-error procedure would repeat until the correct value was stored in the memory element. The auto program controller does not require the controller to switch between program and read modes.

The individual memory bit cells may be implemented using the design described in the commonly assigned U.S. patent application Ser. No. 17/838,718, filed on Jun. 13, 2022, entitled “MEMORY CELL SELECTOR FOR HIGH-VOLTAGE SET AND REST OPERATIONS,” which is incorporated herein by reference. The bit cells may be fabricated to have a high-conductance ON state. A RESET command may cause the RRAM bit cell to change to a lowest conductance (i.e., high impedance) state. In some embodiments, the auto programming procedure described below may be performed after a full SET command. Then, the auto programming procedure may apply a specified RESET program voltage to begin rapidly driving the conductance of the bit cell towards a target conductance. The output conductance may be monitored during this programming procedure, and the programming may stop when the conductance level is near the target output conductance (e.g., within a first threshold). After nearing the target output conductance, the programmer may switch to a pulsed voltage to more precisely approach the target output value using smaller incremental steps (e.g., until within a second threshold). Other embodiments using different RRAM cells may instead apply a full RESET, then begin applying SET voltages to gradually increase towards the target program value.

Specifically, the auto program controller may be configured to continuously monitor the output of the memory element while the programming voltages are applied instead of switching between modes and iterating between programming and reading the outputs. This cannot be accomplished using existing controllers because the read bias voltage that is favorable for reading the conductance could not be applied while also programming the bit cell. As described below, the auto program controller includes circuits configured to monitor the output and detect even small changes in the output conductance (e.g., a difference of less than 1 microsiemens of conductance, or as little as 1% change in conductance). Therefore, the auto program controller may include new functionality that monitors conductance while in the programming mode despite the unfavorable bias conditions applied to the memory element while programming.

In order to program very large and dense memory arrays in seconds rather than days, some embodiments may also distribute the auto program controllers such that program operations may be performed in parallel. For example, some embodiments may pair an auto program controller with each individual memory element in the array. This may be contrasted with existing solutions with a central controller or CPU that programs and reads large blocks of memory elements together.

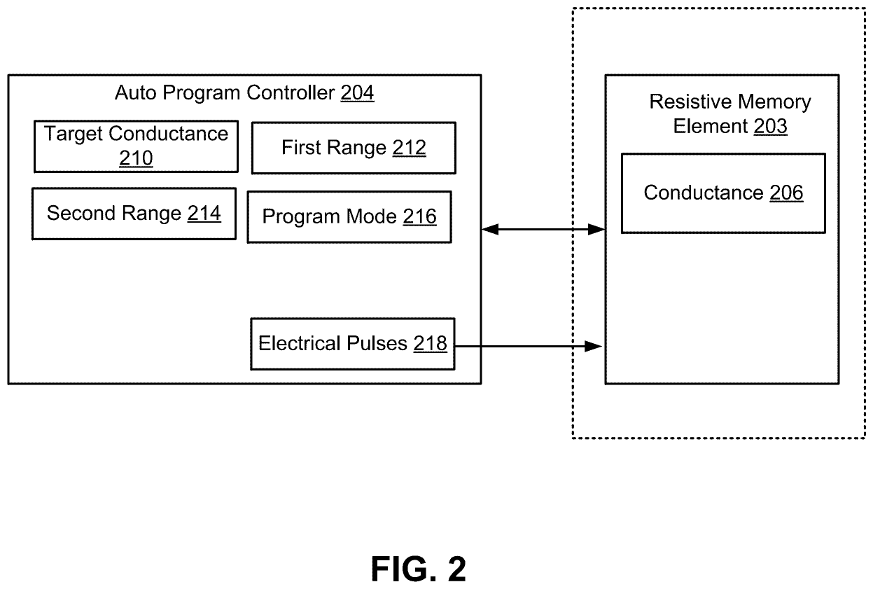

FIG. 2 illustrates a controller 204 for a resistive memory element 203, according to some embodiments. The controller 204 may be the same as or different from the controller 104 shown in FIG. 1. Similarly, the resistive memory element 203 may be the same as or different from the resistive memory element 103 shown in FIG. 1. The controller 204 may have multiple modes. For example, the controller 204 may have a read mode that may enable the controller 204 to read the resistive memory element 203. For example, the read mode may enable the controller 204 to perform a read operation. The read mode may be a different operating mode than the program mode. Reading the resistive memory element 203 in the read mode may involve applying a small voltage across the resistive memory element 203 and determining the conductance 206 of the resistive memory element 203 by measuring a current passing through the resistive memory element 203. The controller 204 may also have a standby mode that may be enabled to conserve energy while waiting for instructions. The controller 204 may also have a program mode that may enable the controller 204 to write data to the resistive memory element 203.

In some embodiments, the controller 204 may apply a voltage to the resistive memory element 203 to adjust the conductance 206. For example, the controller may apply a gradually increasing voltage to gradually increase the conductance 206. The controller 204 may adjust the conductance 206 until the conductance 206 is within a first range 212 of the target conductance 210. The first range 212 may be pre-determined or may be provided manually as an input.

In some embodiments, the controller may apply one or more electrical pulses 218 to the resistive memory element 203. In some embodiments, the controller 204 may include a phase shift detector that may determine a change in the conductance 206 of the resistive memory element 203 based on the electrical pulses 218.

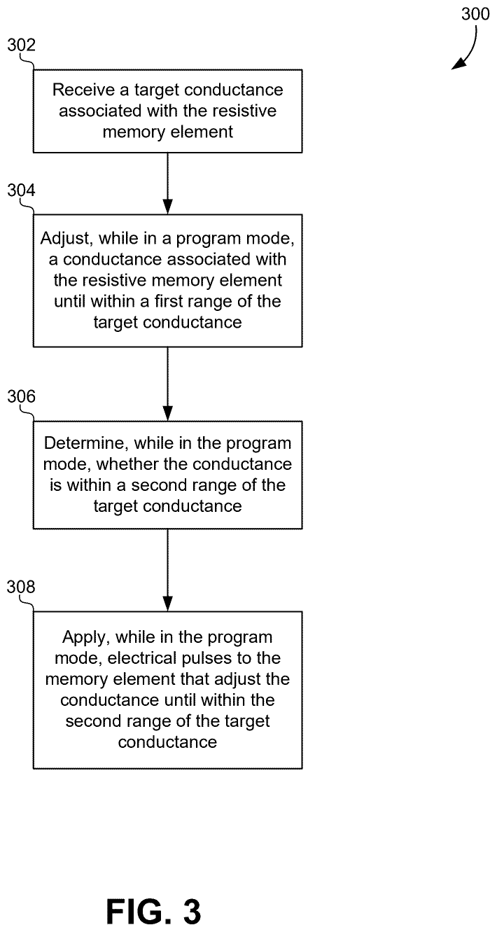

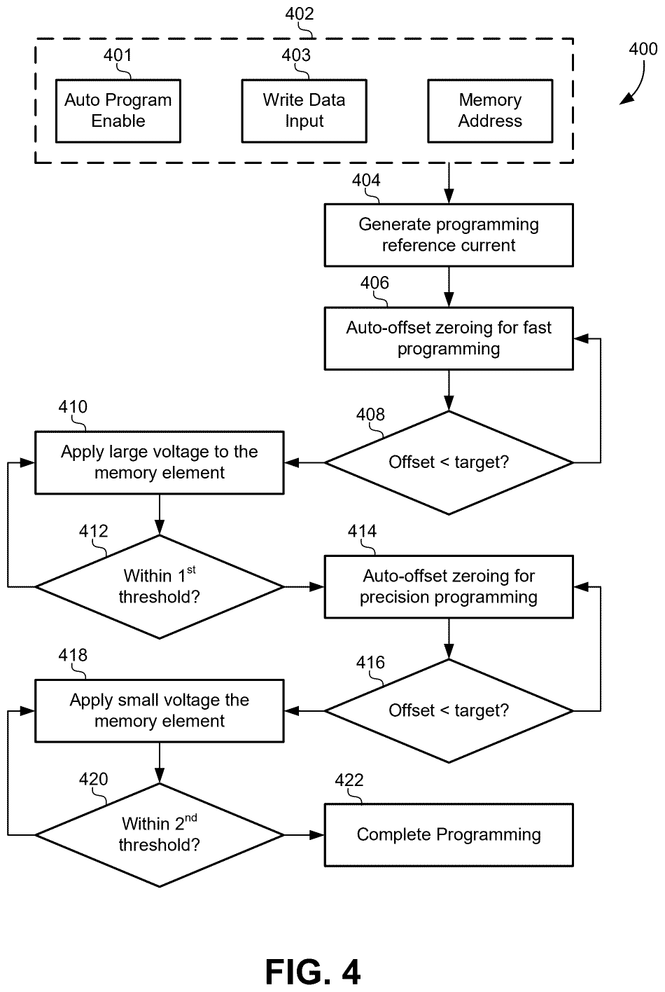

FIG. 3 illustrates a flowchart for a process 300 for programming a resistive memory element, according to some embodiments. The method may be performed using components of FIG. 1, FIG. 2, or a combination thereof. FIG. 4 illustrates a flowchart of a process 400 executed by the controller for programming a resistive memory element, according to some embodiments. The operations of process 400 may include additional optional sub-operations for the more general operations described in process 300.

The process 300 may include receiving, by a controller that is associated with a resistive memory element, a target conductance associated with the resistive memory element. For example, the controller may be implemented as an auto program controller as described herein. The controller itself may be implemented using discrete digital components, such as registers, logic gates, comparators, analog circuits, and so forth, to implement the custom functionality described below. This embodiment may be advantageous when the auto program controller is provided for each individual memory element. Alternatively, the controller may be implemented by a microcontroller or microprocessor. The microcontroller or microprocessor may execute instructions that are stored in a memory (e.g., a non-transitory medium) that cause the controller or microprocessor to execute the following operations.

More specifically in process 400, the controller may receive a set of inputs (402). In some embodiments, the inputs may include a signal 401 to enable an auto program procedure associated with a resistive memory element, along with a target conductance associated with the resistive memory element. In some embodiments, the auto program controller may include a plurality of operating modes, including standby, READ, SET, RESET, auto programming mode, MAC mode, and others. The auto program mode may cause the controller to perform the operations described below and may be contrasted with the traditional READ, SET, and/or RESET modes that may be used during normal operation of the memory. The inputs may include a memory address 405 of a resistive memory element to be programmed by the controller. The inputs may also include a data value such as a write data input 403 to be written to the resistive memory element corresponding to the memory address.

The controller may generate a reference current (404). The reference current may correspond to the data to be written to the resistive memory element. In some embodiments, the reference current may be equivalent to an expected output current that that should be generated in the resistive memory element when a read bias voltage will be applied after the memory element has been programmed. For example, the reference current may be generated to match the expected output current from the resistive memory element after the memory element has been programmed to reach the target conductivity (e.g., when the data has been written to the resistive memory element). Since the resistive memory element may be configured to store many different values between the SET and RESET values (e.g., more than just logic 1 and logic 0), each memory value may be associated with a corresponding output current that should result when the read bias voltage is applied when the controller switches to the programming mode. Since the desired output current for a given value will be known, that output current may be selected and used to generate a corresponding equivalent reference current. The auto programming mode may therefore use the write data input 403 to select or generate the programming reference current.

The process 300 may also include adjusting, while the controller is in a program mode, a conductance associated with the resistive memory element until the conductance is within a first range of the target conductance (304). This operation may be referred to as a “quick program,” “rapid program,” and/or “coarse program” operation, as it is meant to rapidly adjust the conductance of the memory element to within a relatively large, first threshold of the target conductance. More specifically in process 400, the controller may initiate an auto-offset zeroing procedure for the initial programming input (406). This may involve adjusting a bias voltage to reduce an offset voltage. This initial zeroing procedure may provide a bias voltage for programming the bit cell. This may be contrasted with other biasing procedures that may be used to bias the bit cell when reading the stored value. As described below, the auto programming controller may read bias the bit cell individually after each programming signal/voltage is applied in order to read and analyze the output value after every programming input is applied. The controller may determine whether the offset is below a target offset voltage (408). If the offset voltage exceeds the target voltage, the controller may repeat the auto offset zeroing procedure. If the offset voltage is less than or about equal to the target voltage, the auto program controller may proceed to the programming operations.

The controller may apply a relatively large voltage to the resistive memory element to adjust the conductance associated with the resistive memory element (410). In some embodiments, the voltage may be applied as a continuously increasing voltage, a constant voltage sustained over a period of time, as a series of pulses, or in any other suitable form. For example, when starting at a high-conductance SET state, the auto program controller may apply a RESET voltage that is within 15%, within 10%, or within 5% of a specified voltage for the particular write data input 403. This specified voltage may be previously determined to be within a known range for that particular memory value. However, because of the variation between memory elements, it may be assumed that the specified voltage will not precisely drive the memory element to the required resistance. Instead, this specified voltage may be configured to drive the state of the memory elements within a first threshold of the target output current.

The auto program controller may then determine whether the conductance of the resistive memory element is within a first range of the target conductance (412). If the conductance is not within the first range of the target conductance, the controller may apply another voltage to the memory element to further adjust the conductance (410). This process may be repeated until the conductance of the memory element is within the range of the first threshold of the target conductance. The first threshold may be relatively large, such as within 15%, within 10%, within 8%, within 6%, and so forth. Note that conductance is measured and compared in these operations. However, other values may be interchangeable with conductance, such as a current flow from the memory element.

After adjusting the conductance of the memory element to be within the first threshold, the auto program controller may transition into a precision programming mode configured to find-tune the conductance value to be precisely equivalent to the programming reference current. The process 300 may additionally include determining by the controller while still in the programming mode, whether the conductance is within a second range of the target conductance (306). The process 300 may also include applying, by the controller and while the controller is in the program mode, electrical pulses to the resistive memory element that adjust the conductance associated with the resistive memory element until the conductance is within the second range of the target conductance. More specifically in process 400, the auto offset zeroing procedure may be repeated (414), although this time for the adjusted output of the memory element. By applying a new offset to zero the measurements, the auto program controller may detect small deviations between a current output and a subsequent output after a precision voltage is applied to the memory element. As described above, this the offset voltage may be adjusted until the signal is properly zeroed (416).

For the precision programming procedure, the auto program controller may apply a relatively small voltage to the memory element (418). For example, the controller may apply electrical pulses to the resistive memory element that adjust the conductance associated with the resistive memory element. The number and timing of these pulses may be adjusted based on how much the conductance of the memory element needs to be adjusted. For example, the controller may apply relatively large pulses, relatively long pulses, or a relatively large number of pulses initially as the conductance is further away from the target conductance. As the conductance converges on the target conductance, these pulses may be reduced in number, length, and/or magnitude to work precisely approach the target conductance. In comparison to the larger voltages previously applied to the memory element (410), the smaller pulses may have less than 25%, less than 20%, less than 15%, less than 10%, and so forth of the power of the larger voltage pulses.

The controller may then determine whether the conductance of the resistive memory element is within the second threshold of the target conductance (420). If the conductance is not within the first range, the controller again may apply the small voltage input(s) to the memory element (418). As described above, characteristics of these smaller voltages may be reduced as the conductance nears the second threshold. The second threshold may be smaller than the first threshold, such as within about 5%, within about 4%, within about 3%, within about 2%, within about 1% or less of the target conductance. If the conductance is within the second threshold of the target conductance, the auto program controller may complete the programming process (422).

The processes illustrated in FIG. 3 and FIG. 4 may be carried out by individual auto program controllers associated with individual memory elements in the array. In some embodiments, where the arrays are relatively large, these processes may be carried out by multiple auto program controllers in parallel on different memory elements. This allows the memory array to be auto programmed within seconds.

It should be appreciated that the specific steps illustrated in FIGS. 3-4 may provide particular methods according to various embodiments. Other sequences of steps may also be performed according to alternative embodiments. For example, alternative embodiments may perform the steps outlined above in a different order. Moreover, the individual steps illustrated in FIGS. 3-4 may include multiple sub-steps that may be performed in various sequences as appropriate to the individual step. Furthermore, additional steps may be added or removed depending on the particular applications. One of ordinary skill in the art would recognize many variations, modifications, and alternatives.

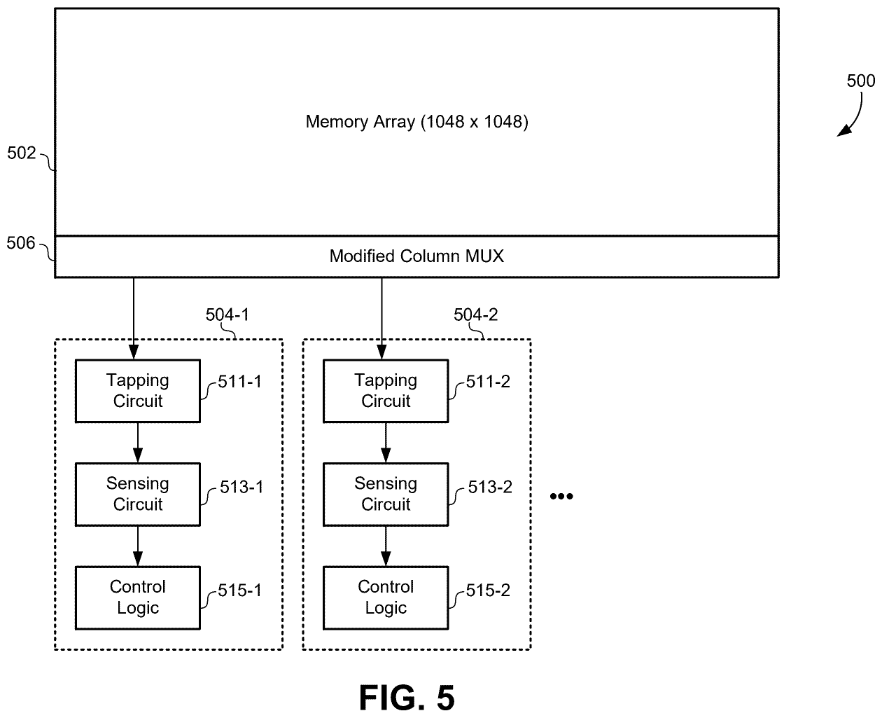

FIG. 5 illustrates a memory tile 500 with parallel auto program controllers, according to some embodiments. The memory tile 500 may include an array of resistive memory elements 502. In some embodiments, the array of resistive memory elements 502 may be the same as the array of resistive memory elements 102 and may include the resistive memory element 103 and/or 203 as described above. The memory tile 500 may be one of many memory tiles in an overall memory array or system. By way of example, the memory tile 500 may include an array of resistive memory elements 502 that is approximate 1 kB by 1 KB in size. These memory elements may be arranged in 1048 columns.

The array of resistive memory elements 502 may include a modified column multiplexer 506. The modified column multiplexer 506 may be the same as or different from the column multiplexer 106 described above. The modified column multiplexer 506 may include circuits for selecting a column within the array of resistive memory elements 502. In some embodiments, the modified column multiplexer 506 may include additional circuits for facilitating a pulse program. For example, the column multiplexer 506 may include one or more pulse generators. In some embodiments, the column multiplexer 506 may include one or more bias voltage inputs for adjusting a bias voltage associated with the column multiplexer 506. The pulse generator and/or the biasing circuits may be used to perform the operations described above for the quick and precision programming processes in FIG. 3 in FIG. 4.

The modified column multiplexer 506 may also include bit lines that may transmit electrical signals to and from the columns of resistive memory elements. In this embodiment, each bit line from a column through the modified column multiplexer 506 may be coupled to individual auto program controllers 504. As described above, individual memory elements may be associated with individual auto program controllers. In some examples, groups of resistive memory elements may share unique controllers. In this embodiment, columns of memory elements may share an auto program controller. This allows the memory tile 500 to program an entire row in the array of resistive memory elements 502 in parallel. Alternatively, sections of each row may share an auto program controller. For example, 8-bit sections in each row may share an auto program controller. In another example, 16-bit sections in each row may share an auto program controller, depending on the embodiment.

In some examples, the controllers 504 may include one or more tapping circuits 511 for receiving signals from the bit line. The tapping circuits 511 may be configured to receive the programming current and convert the programming current into a signal that the sensing circuit can detect. In some examples, the controller may include one or more sensing circuits 513 for processing signals from the modified column multiplexer 506. In some examples, the controller may include control logic 515 that may be coupled to the sensing circuits 513 for controlling the sensing circuits 513. In some embodiments, the control logic 515 may receive inputs for enabling a program mode of the controllers 504. Additionally, the controllers 504 may include a phase shift detector in the sensing circuits 513 that may detect a phase difference between a pulse from the resistive memory element and a pulse from a reference pulse generator. In some embodiments, the tapping circuits may receive the pulse from the reference pulse generator and provide the pulse to the sensing circuits 513 and/or the phase shift detector.

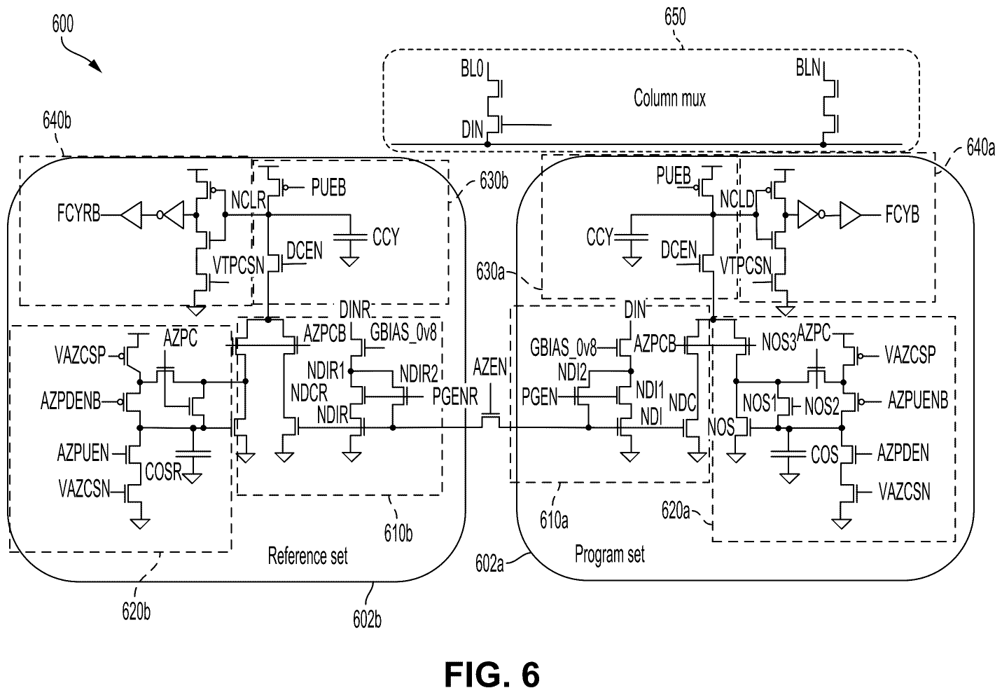

FIG. 6 illustrates a sensing circuit (600), according to some embodiments. In some embodiments, the sensing circuit may be included in a controller, such as the controller 104, 204, and/or 504. The sensing circuit may include tapping circuits (610-1 and 610-2), auto offset zeroing circuits (620-1 and 620-2), cycling circuits (630-1 and 630-2), tripping detector circuits (640-1 and 640-2), or any combination thereof. The sensing circuit (600) may access one or more resistive memory elements via the column multiplexer (650). The sensing circuit 600 may include a program circuit 602-1 and a reference circuit 602-2. In some embodiments, the program circuit 602-1 may be associated with the resistive element being programmed. The reference circuit 602-2 may be associated with the desired data value (i.e., the reference circuit 602-2 may represent a desired state of the resistive memory element.) The sensing circuit (600) may output signals FCYB and FCYRB and may transmit signals FCYB and FCYRB to a phase shift detector.

In some embodiments, the tapping circuit 610-1 may receive a data signal DIN from the column multiplexer 650. The program current DIN may be associated with a resistive memory element in an array of resistive memory elements that may be coupled to the column multiplexer 650. In some embodiments, the program current DIN may be indicative of a conductance of the resistive memory element. For example, the program current DIN may be a current that passes through the resistive memory element while the controller is in a program mode. The tapping circuit 610-1 may transmit the program current DIN to other components of the sensing circuit 600. In some embodiments, the tapping circuit 610-1 may modify the program current DIN to condition the program current DIN for use by the sensing circuit 600. For example, the tapping circuit 610-1 may amplify the program current DIN. In some embodiments, the tapping circuit 610 may convert the program current DIN to a time-domain current.

In some embodiments, the tapping circuit 610-2 may receive a reference current DINR that may be generated by the controller. The reference current DINR may be equivalent to an expected output current that that should be generated in the resistive memory element when a read bias voltage will be applied after the memory element has been programmed.

In some embodiments, the auto-offset zeroing circuits 620-1 and 620-2 may adjust an offset voltage associated with certain portions of the program circuit 602-1 and the reference circuit 602-2. The auto-offset zeroing circuits 620-1 and 620-2 may each include an offset capacitor that may determine an offset voltage associated with the program circuit 602-1 and the reference circuit 602-2, respectively. For example, the offset capacitor COS may determine the offset voltage associated with the program circuit 602-1, and the offset capacitor COSR may determine the offset voltage associated with the reference circuit 602-2. Each offset capacitor may receive one or more signals that may charge the capacitor. Each auto-offset zeroing circuit may include inputs that may receive the one or more signals.

In some embodiments, cycling circuit 630-1 may enable a cyclic charging and discharging process of a cycling capacitor (CCY) based on the conductance of the resistive memory element. Similarly, cycling circuit 630-2 may enable a cyclic charging and discharging process of a different cycling capacitor based on the target conductance. The CCY may have a voltage level NCLD that may affect a tripping detector in the tripping circuit 640-1. The tripping circuit 640-1 may output a signal FCYB that may be received by a phase shift detector circuit. Similarly, the tripping circuit 640-2 may output signal FCYRB based on the voltage level NCLR. The phase shift detector circuit may receive output signals FCYRB and FCYB to determine a difference in phase between the output signals. Based on the difference in phase, a go-stop detector that is coupled to the phase shift detector circuit may cause the controller to apply additional electrical pulses. Alternatively, the go-stop detector may, based on the difference in phase, prevent the controller from applying additional electrical pulses.

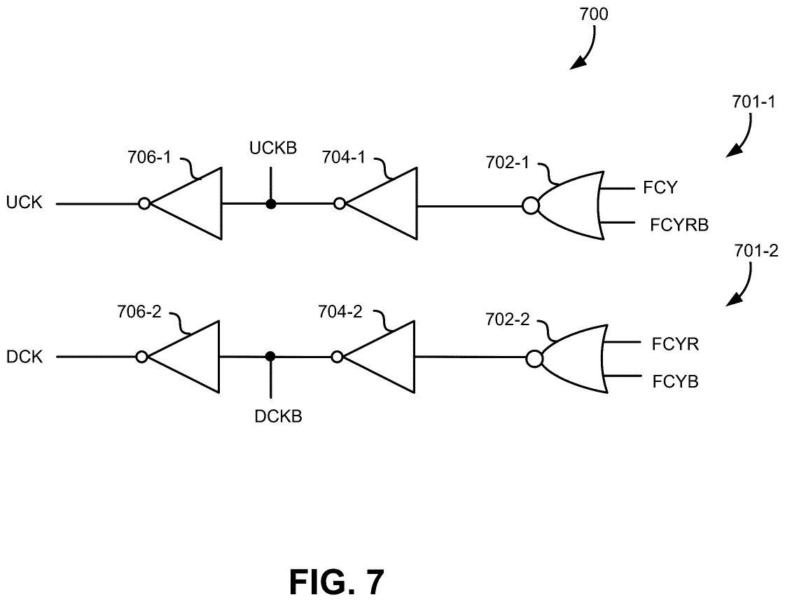

FIG. 7 illustrates a phase shift detector circuit 700, according to some embodiments. The phase shift detector circuit 700 may be coupled to the sensing circuit 600 from FIG. 6 and may be included in the controller 104, 204, and/or 504. The phase shift detectors 701-1 and 701-2 may receive output signals FCYB and FCYRB, respectively, from the sensing circuit 600. In some embodiments, the phase shift detector 700-1 may be associated with the reference output signal FCYRB. In some embodiments, phase shift detector 701-2 may be associated with the program output signal, FCYB. In some embodiments, the signal FCYB may be received from the tripping circuit 640-1 of the program circuit 602-1. In some embodiments, the phase shift detector may include one or more logic gates. For example, the phase shift detector circuit 700 may include one or more NOR gates followed by one or more pairs of inverters.

In some embodiments, the phase shift detector 701-1 that is associated with the reference circuit may include a NOR gate 702-1 that may accept signals FCY and FCYRB as inputs. The output of the NOR gate 702-1 may be fed into a first inverter 704-1 to generate signal UCKB. The signal UCKB may be fed into a second inverter 706-1 to generate signal UCK, which may be the complement of signal UCKB.

In some embodiments, the phase shift detector 701-2 that is associated with the program circuit may include a NOR gate 702-2 that may accept signals FCYR and FCYB as inputs. The output of the NOR gate 702-2 may be fed into a first inverter 704-2 to generate signal DCKB. The signal DCKB may be fed into a second inverter 706-2 to generate signal DCK, which may be the complement of signal DCKB.

In some embodiments, the phase shift detector circuit 700 may generate one or more digital output signals. For example, the phase shift detector circuit 700 may output signals UCK and DCK, associated with signals FCYB and FCYRB, respectively. The output signals UCK and DCK of the phase shift detector circuit 700 may be transmitted to a go-stop detector. The go-stop detector may use output signals UCK and DCK to establish a timing difference between electrical pulses that may have passed through a resistive memory element and electrical pulses that may have been generated by a reference pulse generator. The go-stop detector may use signals UCK and DCK (and a timing difference associated therewith) to determine whether to continue programming the resistive memory element with electrical pulses or to complete the programming process associated with the resistive memory element.

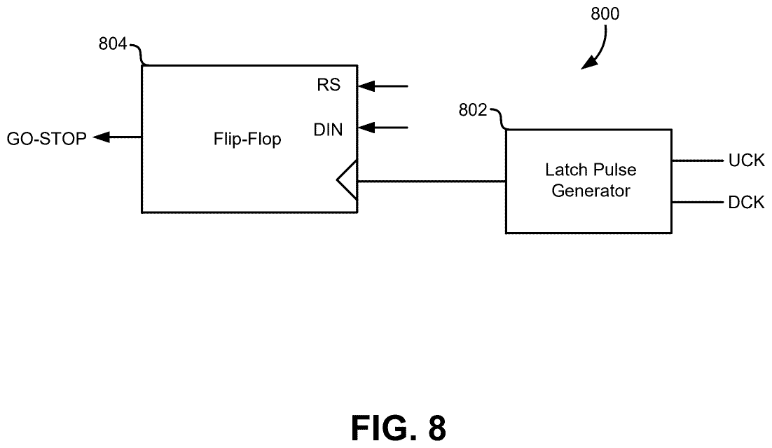

FIG. 8 illustrates a go-stop detector circuit (800) according to some embodiments. The go-stop detector circuit 800 may receive output signals UCK and DCK from the phase shift detector circuit 700. In some embodiments, the go-stop detector circuit may include a latch pulse generator 802 that may receive the signals UCK and DCK as input. Based on the signals UCK and DCK, the latch pulse generator 802 may generate a pulse signal LENB. The latch pulse generator 802 may be coupled to a flip-flop (804) and may transmit the pulse signal LENB to an input of the flip-flop 804. For example, the latch pulse generator 802 may transmit the pulse signal LENB to a clock input of the flip-flop 804. In some embodiments, the flip-flop 804 may be a pulse-driven latch with a reset control. In addition to the signal LENB, the flip-flop 804 may receive a program current DIN from a bit line associated with the resistive memory element. Additionally, the flip-flop 804 may receive a reset signal RS.

The length of the pulse signal LENB may depend on a difference between the length of an electrical pulse that may have been transmitted to a resistive memory element and a reference pulse generated by a reference pulse generator. For example, the signals UCK and DCK may each have a trailing edge that may be detected at different times. In some embodiments, a length of the pulse signal LENB may be equivalent to or based on a time difference between a trailing edge associated with the UCK signal and a trailing edge associated with the DCK signal. Alternatively, the length of the pulse signal LENB may be equivalent to or based on a time difference between a rising edge of the UCK signal and a rising edge of the DCK signal. Any other suitable features of the UCK signal and the DCK signal may be used to determine the length of the pulse signal LENB.

If the conductance of the resistive memory element is similar to the target conductance associated with the reference pulse, the flip-flop 804 may reset. Upon resetting, the flip-flop 804 may send a “go” signal to the sensing circuit 600 for causing the sensing circuit 600 to generate additional electrical pulses and further adjust the conductivity of the resistive memory element associated therewith. However, if the conductance of the resistive memory element is not similar to the target conductance associated with the reference pulse, the LENB pulse may be insufficiently long to cause the flip-flop to reset, thereby halting the electrical pulses and completing the programming process associated with the resistive memory element.

In the foregoing description, for the purposes of explanation, numerous specific details were set forth in order to provide a thorough understanding of various embodiments. It will be apparent, however, to one skilled in the art that embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of the example embodiments will provide those skilled in the art with an enabling description for implementing an example embodiment. It should be understood that various changes may be made in the function and arrangement of elements without departing from the spirit and scope of various embodiments as set forth in the appended claims.

Specific details are given in the foregoing description to provide a thorough understanding of the embodiments. However, it will be understood by one of ordinary skill in the art that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations may be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination may correspond to a return of the function to the calling function or the main function.

In the foregoing specification, aspects various embodiments are described with reference to specific embodiments, but those skilled in the art will recognize that the invention is not limited thereto. Various features and aspects of the above-described embodiments may be used individually or jointly. Further, embodiments may be utilized in any number of environments and applications beyond those described herein without departing from the broader spirit and scope of the specification. The specification and drawings are, accordingly, to be regarded as illustrative rather than restrictive.

What is claimed is:

1. A method comprising:
receiving, by a controller that is associated with a resistive memory element, a target conductance associated with the resistive memory element;
adjusting, by the controller and while the controller is in a program mode, a conductance associated with the resistive memory element until the conductance is within a first range of the target conductance;
determining, by the controller and while the controller is in the program mode, whether the conductance is within a second range of the target conductance; and
applying, by the controller and while the controller is in the program mode, electrical pulses to the resistive memory element that adjust the conductance associated with the resistive memory element until the conductance is within the second range of the target conductance.

2. The method of claim 1, further comprising:
adjusting, by the controller and while the controller is in a program mode, an offset voltage associated with the resistive memory element.

3. The method of claim 1, wherein the resistive memory element is embedded within an array having a plurality of resistive memory elements.

4. The method of claim 3, wherein each resistive memory element in the plurality of resistive memory elements is associated with a unique controller in an array of controllers.

5. The method of claim 1, wherein determining, by the controller, whether the conductance is within a second range of the target conductance further comprises determining, by a phase shift detector associated with the controller and based on a phase shift of an electrical pulse applied by the controller to the resistive memory element, a change in conductance of the resistive memory element.

6. The method of claim 1, further comprising adjusting, by the controller, a pulse duration of the electrical pulses based on a difference between the conductance of the resistive memory element and the target conductance.

7. The method of claim 1, further comprising selecting a resistive memory element by:
providing a row value corresponding to the resistive memory element to a row decoder; and
providing a column value corresponding to the resistive memory element to a column multiplexer.

8. A system comprising:
a resistive memory element; and
a controller that is coupled to the resistive memory element and is configured to perform operations comprising:
receiving, target conductance associated with the resistive memory element;
adjusting, while the controller is in a program mode, a conductance associated with the resistive memory element until the conductance is within a first range of the target conductance;
determining whether the conductance is within a second range of the target conductance; and
applying, while the controller is in the program mode, electrical pulses to the resistive memory element that adjust the conductance associated with the resistive memory element until the conductance is within the second range of the target conductance.

9. The system of claim 8, wherein the controller further comprises an auto-offset zeroing circuit that is configured while the controller is in the program mode to adjust an offset voltage associated with the resistive memory element.

10. The system of claim 8, wherein the controller further comprising a cycling circuit that is configured to generate clocked pulses that are used to generate the electrical pulses.

11. The system of claim 8, further comprising a tapping circuit that is configured to receive a data signal from a column multiplexer associated with the resistive memory element.

12. The system of claim 8, further comprising a tripping detector circuit that is configured to, in response to receiving a signal from a flip flop, enable the controller to apply the electrical pulses.

13. The system of claim 12, further comprising a phase-shift detector that is configured to determine a timing difference between an electrical pulse applied to the resistive memory element and a reference electrical pulse provided from a reference electrical pulse generator.

14. The system of claim 13, further comprising a go-stop detector that is configured to, in response to receiving an output from the phase-shift detector, provide a go signal to the tripping detector circuit.

15. A controller that is coupled to a resistive memory element and is configured to perform operations comprising:
receiving a target conductance associated with the resistive memory element;
adjusting, while the controller is in a program mode, a conductance associated 4 with the resistive memory element until the conductance is within a first range of the target conductance;
determining, by the controller, whether the conductance is within a second range of the target conductance; and
applying, by the controller and while the controller is in the program mode, electrical pulses to the resistive memory element that adjust the conductance associated with the resistive memory element until the conductance is within the second range of the target conductance.

16. The controller of claim 15, further comprising a phase-shift detector that includes:
a first input that is configured to receive a program current from the resistive memory element;
a second input that is configured to receive a reference current from a reference pulse generator;
a first output that is configured to transmit a first digital output signal based on the program current; and
a second output that is configured to transmit a second digital output signal based on the reference current.

17. The controller of claim 16, further comprising a latch pulse generator that is configured to generate a pulse signal based on the first digital output signal and the second digital output signal, the pulse signal having a duration that is substantially similar to a time difference between the first digital output signal and the second digital output signal.

18. The controller of claim 15, wherein groups of resistive memory elements share unique controllers in an array of controllers.

19. The controller of claim 15, wherein the controller includes a read mode that applies a read bias to a memory array during a read operation, and the read mode comprises a different operating mode than the program mode.

20. The controller of claim 17, further comprising a flip-flop that is configured to:
receive the pulse signal; and
generate, based on the duration of the pulse signal, a signal that is receivable by a tripping detector of the controller.
